(19) United States
(12) Patent Application Publication
(10) Pub. No.: US 2013/0198578 A1
(43) Pub. Date: Aug. 1, 2013

(54) Maximizing Re-Use of External Pins of an Integrated Circuit for Testing

(71) Applicants: Ramesh Kumar Chandel, Bangalore (IN); Prasanth ViswanathanPillai, Bangalore (IN)

(72) Inventors: Ramesh Kumar Chandel, Bangalore (IN); Prasanth ViswanathanPillai, Bangalore (IN)

(73) Assignee: TEXAS INSTRUMENTS INCORPORATED, Dallas, TX (US)

(21) Appl. No.: 13/363,604

(22) Filed: Feb. 1, 2012

(51) Int. Cl. G01R 31/3177; G06F 11/25

(52) U.S. Cl. 714/727; 714/733; 714/E11.155

(57) ABSTRACT

At least one external pin of an integrated circuit (IC) is coupled to receive a first configuration signal used in configuring an internal circuit block for a test designed to uncover faults in the circuit block, and to receive a first test signal during the test. Configuration logic in the IC is designed to generate control data by decoding configuration signals that include the first configuration signal. A test configuration register stores the control data and applies the control data during the test, but is decoupled from the configuration logic prior to commencement of the test. A sequence detector in the IC is designed to detect a reset sequence signifying an end of the test and in response to re-couple the test configuration register to the configuration logic. The number of external pins needed for testing the IC is reduced.

### BACKGROUND

1. Technical Field

Embodiments of the present disclosure relate generally to integrated circuit (IC) testing, and more specifically to techniques for maximizing re-use of external pins of an integrated circuit for testing.

2. Related Art

Integrated circuits (IC) typically need to be tested to uncover faults in circuitry within the ICs. For example, post-fabrication testing is usually performed on ICs. Typically, an IC is connected to an external tester via the external pins of the IC. The tester then generates test patterns, provided to the IC via the external pins. The response of one or more internal blocks or circuitry in the IC to the test patterns may be read back by the tester, also via the external pins. Any faults in the IC may be determined by the tester based on analysis of the response. The IC itself may be designed with circuitry for enabling such testing, and such design techniques that incorporate testability features in an IC are generally referred to as design for testability or DFT. An example type of test that may be performed on an IC is a scan-based test, well known in the relevant arts.

To minimize test cost (for example cost incurred in use of a tester) and/or test time, it may be desirable to test multiple ICs simultaneously, i.e., in parallel. Thus, a same test (i.e., with the same test patterns, etc) may be performed simultaneously on the multiple ICs (typically of the same type/functionality). The number of ICs that can be tested simultaneously is usually limited by the number of pins available on the tester used to perform the test. Thus, for any given number of tester pins, the number of ICs that can be tested simultaneously is increased if the number of test pins required per IC is smaller. To this end, an IC may be designed to enable a same external pin on the IC to be used as a test pin (i.e., to send or receive a test signal during testing) in addition to providing normal functionality, i.e., the external pin which provides normal functionality (i.e., carries the intended signal/s in normal functional mode of operation) is re-used as a test pin during testing. Such re-use of a pin also leads to lower packaging cost of the IC. It may be desirable to maximize the number of such pins for re-use during testing.

### SUMMARY

This summary is provided to comply with 37 C.F.R. §1.73, requiring a summary of the invention briefly indicating the nature and substance of the invention. It is submitted with the understanding that it will not be used to interpret or limit the scope or meaning of the claims.

An integrated circuit (IC) comprising a plurality of external pins, a configuration logic, a test configuration register and a sequence detector. The plurality of external pins includes a first set of external pins. At least one external pin in the first set is coupled to receive, during a configuration phase, a first configuration signal used in configuring a circuit block internal to the IC for a test designed to uncover faults in the circuit block, but is coupled to receive a first test signal during the test. The configuration logic is designed to generate control data by decoding configuration signals received during the configuration phase, the control data being designed to configure the circuit block for the test. The first configuration signal is included in the configuration signals. The test configuration register is coupled to the configuration logic during the configuration phase to receive the control data. The test configuration register is designed to store and apply the control data during the test, but is decoupled from the configuration logic at the end of the configuration phase and prior to commencement of the test. The sequence detector is designed to detect a reset sequence signifying an end of the test, and to re-couple the test configuration register to the configuration logic in response to detecting the reset sequence. In an embodiment, the first set of external pins is connected to the JTAG terminals of a JTAG engine in the IC.

Several embodiments of the present disclosure are described below with reference to examples for illustration. It should be understood that numerous specific details, relationships, and methods are set forth to provide a full understanding of the embodiments. One skilled in the relevant art, however, will readily recognize that the techniques can be practiced without one or more of the specific details, or with other methods, etc.

### BRIEF DESCRIPTION OF THE VIEWS OF DRAWINGS

Example embodiments will be described with reference to the accompanying drawings briefly described below.

FIG. 1 is a diagram illustrating an example test environment for testing integrated circuits (IC).

FIG. 2 shows an IC with five external pins connected to a JTAG engine.

FIGS. 3 and 4 together show relevant details of an IC in an embodiment.

FIG. 5 is a diagram illustrating configuration and test sequences performed on an IC in an embodiment.

FIG. 6 shows a sequence generated by a tester to enable an IC to determine end of a test phase, in an embodiment.

FIG. 7 is a diagram illustrating details of multiple levels of de-multiplexing implemented in an IC in another embodiment.

FIG. 8 is a diagram illustrating the manner in which an external pin can be used to serve as a functional pin in addition to as a test pin, in an IC in yet another embodiment.

The drawing in which an element first appears is indicated by the leftmost digit(s) in the corresponding reference number.

### DETAILED DESCRIPTION

Various embodiments are described below with several examples for illustration.

1. Example Test Environment

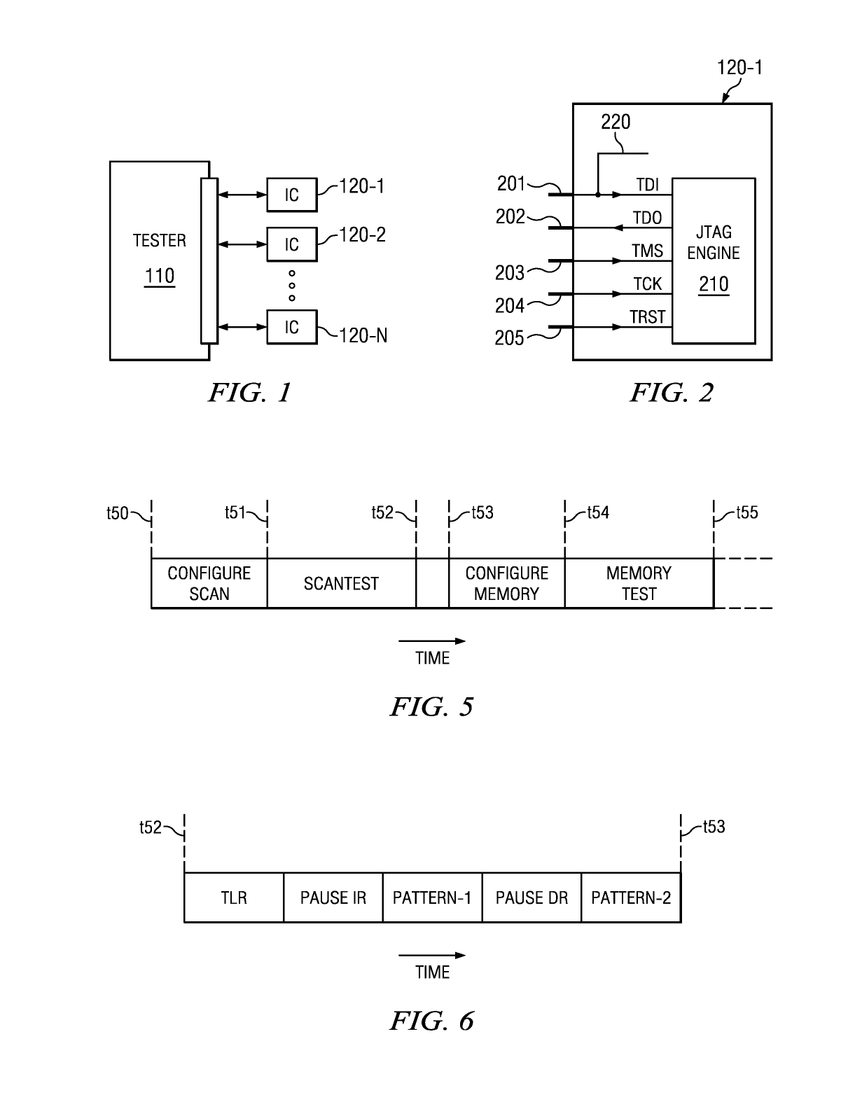

FIG. 1 is a diagram illustrating an example test environment for testing integrated circuits (IC). ICs 120-1 through 120-N are integrated circuits that are to be tested. Tester 110 generates configuration data for configuring ICs 120-1 through 120-N for operation in test mode. Tester 110 generates test data (e.g., sequences of binary values designed to identify faults in each of ICs 120-1 through 120-N). Tester 110 applies the test data to each of ICs 120-1 through 120-N. ICs 120-1 through 120-N send the results of the test (based on the test data) back to tester 110, which then analyzes the results to determine if one or more circuits (or circuit blocks) in ICs 120-1 through 120-N is/are faulty or not. Some examples of test procedures applied on ICs 120-1 through 120-N are sequential scan-tests, memory tests for testing on-chip memory, etc.

As noted above, a same test procedure may simultaneously be applied on each of ICs 120-1 through 120-N, and ICs 120-1 through 120-N may be identical to each other. In general, it is desirable for reasons such as for example, cost of tester usage time, that the number of ICs tested simultaneously be maximized. Such a requirement is usually related to the number of pins on each IC (e.g., ICs 120-1 through 120-N) that are required to enable the test to be performed. Generally, lesser the number of pins (termed test pins for convenience) required to be ‘touched’ on each IC during testing, greater the number of ICs that can be tested simultaneously, given a total number of pins available on tester 110.

One technique that is used to minimize the number of test pins on an IC is to re-use some of the JTAG pins on an IC. As is well known in the relevant arts, JTAG refers to the Joint Test Action Group specification (standardized as the IEEE 1149.1 Standard) that specifies a Test Access Port and a Boundary-Scan Architecture for ICs for purposes such as for testing circuitry on a printed circuit board, in-circuit emulation and debugging, etc. JTAG specifies five signals, namely, TDI, TDO, TMS, TCK and TRST, and the specifications of these signals may be obtained from the IEEE 1149.1 standard.

As used herein, the term ‘JTAG pin’ refers to an external pin (of an IC) that is connected to a JTAG engine (in the IC) and serves to carry any of signals TDI, TDO, TMS, TCK or TRST as defined in the IEEE 1149.1 standard. FIG. 2 shows an IC (IC 120-1) with five external pins (IC pins) connected to a JTAG engine (or JTAG state-machine, numbered 210) as defined by the IEEE 1149.1 standard. External pins 201 through 205 are shown respectively providing external connectivity to JTAG signals TDI, TDO, TMS, TCK and TRST from JTAG engine 210, and are therefore referred to as JTAG pins (first set of external pins). Although only five external pins (201-205) of IC 120-1 are shown for conciseness, IC 120-1 may contain many more external pins (for example, input/output pins for functional signals, i.e., pins that carry signals that are generated during normal functional operation (as against a test mode operation) of IC 120-1).

To minimize the number of test pins required for testing IC 120-1, some of IC pins 201 through 205 may additionally be connected to other circuitry (i.e., other than JTAG engine 210) within IC 120-1. As an example, pin 201 may be used via path 220 for connection to an input of a scan chain configured for a sequential scan test, and may thus serve as a ‘scan-in’ (SI) pin during the sequential scan test. Suitable circuitry (not shown in FIG. 2) may be implemented in IC 120-1 to enable the use of pin 201 both as a TDI input pin of JTAG engine 220, as well as an SI pin for scan tests. For example, a pair of tri-state buffers could be used for such purpose.

It may be desirable to re-use all of pins 201 through 205 to serve as test pins (for testing of circuitry within IC 120-1), in addition to providing normal functionality as JTAG pins TDI, TDO, TMS, TCK and TRST.

2. Techniques To Re-Use JTAG Pins as Test Pins for IC Testing

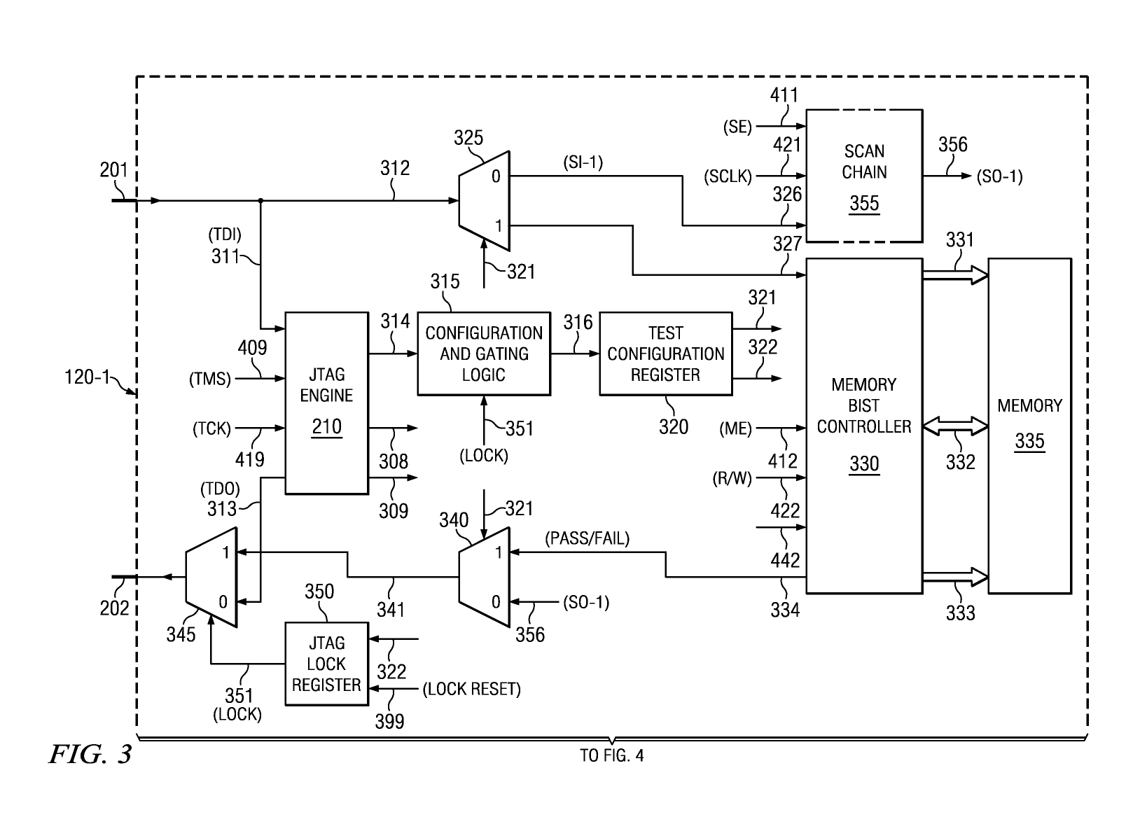

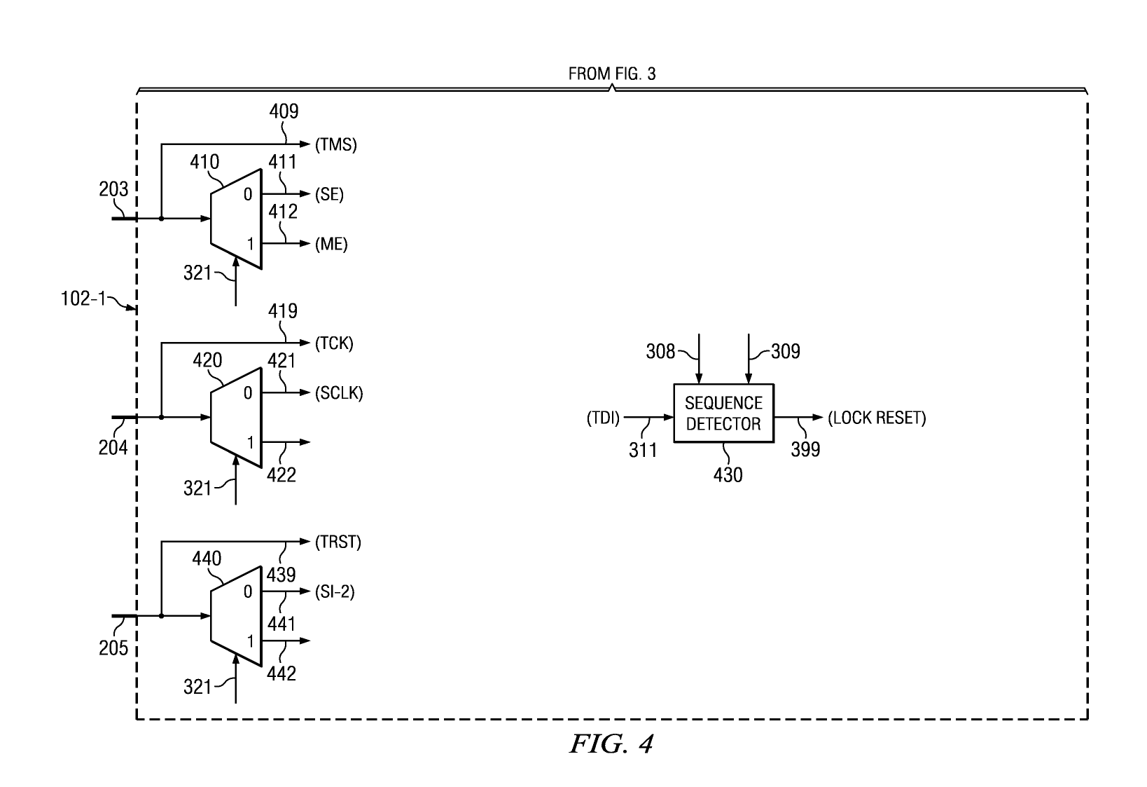

FIGS. 3 and 4 together show relevant details of IC 120-1 in an embodiment. FIG. 3 shows JTAG engine 210, gating logic 315, test configuration register 320, de-multiplexer (DEMUX) 325, memory BIST (Built-In Self Test) controller 330, memory 335, multiplexer (MUX) 340 and 345, JTAG lock register 350, scan chain 355, and pins 201 and 202 of IC 120-1. FIG. 4 shows pins 203, 204 and 205, DEMUX 410, 420, and 440 and sequence detector 430, of IC 120-1. The combination of JTAG engine 210 and configuration-and-gating logic 315 is referred to herein also as ‘configuration logic’.

Scan chain 355 represents a set of memory elements (e.g., flip-flops) contained in the functional portion of IC 120-1. The term ‘functional portion’ refers to circuitry within IC 120-1 that is designed to provide the intended function or operation of IC-120 in normal (functional mode) operation. For example, assuming IC 120-1 is a processor, the functional portion may include arithmetic logic units, registers, microcode sequencer, etc., that enable the processor to provide the corresponding processor functionality. As described below, sequential scan tests may be performed on scan chain 355, which may itself be formed (typically during a configuration phase) into a chain prior to such scan test. Memory 335 may also be considered as part of the functional portion of IC 120-1, and represents on-chip memory, which may be implemented in any suitable form, such as for example, static random access memory (SRAM).

In contrast, the circuits/blocks (except scan chain 355 and memory 335) shown in FIGS. 3 and 4 combined represent circuit portions that are designed to facilitate testability of IC 120-1, and typically are not involved in normal functional operation of IC 120-1. The circuit elements contained in scan chain 355 may only represent some of the functional portion of IC 120-1, and IC 120-1 may contain more circuitry (not shown), but some or all of which can be configured as corresponding scan chains for testing. Similarly, IC 120-1 may contain more memory blocks similar to memory 335.

External pin 201 is connected to the TDI (test data input) connection (311) of JTAG engine 210, and also to the input of DEMUX 325 via path 312. The connection of external pin 201 via path 312 to DEMUX 325 serves to provide the alternative functionality of external pin 201 as a test pin, as described below.

External pin 202 is connected to the output of MUX 345, whose inputs 341 and 313 (TDO) respective are the output of MUX 340 and the TDO (test data output) connection of JTAG engine 210. Thus, external pin 202 may serve as the TDO output of JTAG engine 210 or as a test pin, as described below.

External pin 203 is connected to the input of DEMUX 410, and to the TMS (test mode select) connection (via path 409) of JTAG engine 210. Thus, external pin 203 is designed to serve as the TMS input of JTAG engine 210, as well as a test pin via connection through DEMUX 410, as described below.

External pin 204 is connected to the input of DEMUX 420, and to the TCK (test clock) connection (via path 419) of JTAG engine 210. Thus, external pin 204 is designed to serve as the TMS input of JTAG engine 210, as well as a test pin via connection through DEMUX 410, as described below.

External pin 205 is connected to the input of DEMUX 440, and to the TRST (test reset) connection (via path 439) of JTAG engine 210. Thus, external pin 205 is designed to serve as the TRST input of JTAG engine 210, as well as a test pin via connection through DEMUX 440, as described below. In an embodiment, pin 205 and the TRST signal of JTAG engine 210 are not implemented.

The operation of the relevant blocks shown in FIGS. 3 and 4 in an embodiment in maximizing the re-use of external pins to serve as test pins is now described with combined reference to FIGS. 3 and 4. In the embodiment, two types of tests, namely, sequential scan test and memory test are performed on IC 120-1 using tester 110. It is assumed that sequential scan test is performed first, followed by memory test.

On reset of IC 120-1, pin 205 is maintained at logic one. As a result, the TRST input of JTAG engine 210 is at logic one, and JTAG mode is enabled. Signal 351 (Lock) is at logic zero, and gating logic 315 is enabled to forward signal 314 on path 316. MUX 345 forwards signal 313 (TDO) on pin 202. Tester 110 transmits configuration data on pin 201, with the configuration data designed to set IC 120-1 in sequential scan test mode. The configuration data are received by JTAG engine 210 via the TDI input 311. Tester 110 generates clock signals on pin 204, which are available on clock terminal TCK (419), to clock-in the configuration data. In addition, tester 110 may control the value of the signal on pin 203 to control the value of signal TMS (409). JTAG engine 210 forwards the configuration data on path 314 to configuration-and-gating logic 315.

Configuration-and-gating logic 315 decodes the configuration data received from JTAG engine 210, and generates corresponding control/configuration bits to set IC 120-1 in sequential scan test mode. The control/configuration bits include those required for creation of scan chains (e.g., such as that for ‘stitching’ the corresponding flip-flops to form scan chain 355), setting of the speed of the clock used for capture in scan testing, appropriate select signals for controlling the operation of components 325, 340, 410, 420 and 440, etc.

Configuration-and-gating logic 315 forwards the control/configuration bits on path 316 to test configuration register 320 for storage. The forwarding of the control/configuration bits on path 316 is enabled only if signal 351 (Lock) enables such forwarding. It is assumed that a logic zero value of signal 351 enables such forwarding, while a logic one value of signal 351 disables such forwarding. Following reset, signal 351 is at logic zero, and the control/configuration bits are forwarded to test configuration register 320 for storage as well as for applying the control/configuration bits to the corresponding signal lines (although not shown in the Figures).

Based on the configuration data received, configuration-and-gating logic 315 sets bit 321 to logic zero. As a result, MUX 340 forwards signal 356 (SO-1) on path 341, DEMUX 325 forwards signal 312 on path 326 (SI-1), DEMUX 410 forwards signal 203 (i.e., signal on pin 203) on path 411 (SE), DEMUX 420 forwards signal 204 on path 421 (SCLK), and DEMUX 440 forwards signal 205 on path 441 (SI-2). The configuration phase corresponding to sequential scan test is depicted in FIG. 5 by interval t50-t51 (“Configure Scan”).

In addition, at the end of the sequential scan test configuration (i.e., once the control/configuration bits corresponding to the sequential scan test have been set/applied) and prior to the start of the sequential scan test, configuration-and-gating logic 315 sets signal 322 to logic one. In response to signal 322 being logic one, JTAG lock register 350 sets signal 351 (Lock) to logic one. A logic one level of signal 351 (Lock) disables the outputs of configuration-and-gating logic 315 (e.g., signal 316) from being forwarded to test configuration register 320. Also, a logic one level of signal 351 selects signal 341 as the output of MUX 345 on pin 202. The sequential scan test configuration effects the following pin configurations:

Pin 201 is connected to the scan-in (input) path 326 (SI-1) of scan chain 355.

Pin 202 is connected to the scan-out (output) path 356 (SO-1) of scan chain 355.

Pin 203 is connected to the scan-enable path 411 (SE) of scan chain 355.

Pin 204 is connected to the scan-clock path 421 (SCLK) of scan chain 355.

Assuming that pin 205 and TRST connection of JTAG engine 210 are implemented, pin 205 is connected to the scan-in path 441 (SI-2) of another scan chain (not shown).

Sequential scan tests are then performed on scan chains such as scan chain 355. While only one scan chain 355 is shown in IC 120-1, more number of scan chains can be created in IC 120-1 with corresponding scan-in, scan-out, scan-clock and scan-enable connections via other pins of IC 120-1. Tester 110 may analyze the response bits corresponding to the scan tests to determine faults in the scan chains. The sequential scan test phase is depicted in FIG. 5 by interval t51-t52 (“SCANTEST”).

Due to the direct connection of pins 201, 203 and 204 to the TDI, TMS and TCK terminals respectively of JTAG engine 210, the bit values on these pins during the sequential scan tests will affect the state of JTAG engine 210 in a manner determined by the specific signal/bit values on these pins. As a result, the inputs (via path 314) to configuration-and-gating logic 315 and the response of configuration-and-gating logic 315 to such inputs may not be predictable. However, such unpredictable effects are not of concern since the inputs to test configuration register 320 via path 316 are disabled (due to signal 351 (Lock) being a logic one), and the configuration data stored in test configuration register 320 are not affected. Hence, the direct connection of pins 201, 203 and 204 to the TDI, TMS and TCK terminals of JTAG engine 210 do not affect the operations of the sequential scan tests.

At the end of the sequential scan tests, tester 110 generates, in interval t52-t53 (shown expanded in FIG. 6), a sequence of signals designed to enable sequence detector 430 to determine that the sequential scan tests are complete. Accordingly, tester sets pin 203 to logic high for a duration equal five clock cycles of the signal provided on pin 204. Since, pin 203 and pin 204 are respectively connected to the TMS and TCK inputs of JTAG engine 210, JTAG engine 210 moves to the test logic reset (TLR) state. Tester 110 then generates a sequence of signals on pins 203 and 204 to cause JTAG engine 210 to enter the Pause-IR state, as defined in the IEEE 1149.1 standard. Tester 110 then generates a pre-determined bit-pattern (pattern-1) on pin 201. Tester 110 then generates a sequence of signals on pins 203 and 204 to cause JTAG engine 210 to enter the Pause-DR state, as defined in the IEEE 1149.1 standard. Tester 110 then generates a pre-determined bit-pattern (pattern-2) on pin 201. FIG. 6 illustrates the sequence that occurs in interval t52-t53, and as noted above.

Sequence detector 430 receives as signals 308, 309 and 311 (TDI) as inputs. Signal 308 indicates whether JTAG engine 210 is in Pause-IR state or not, while signal 309 indicates whether JTAG engine 210 is in Pause-DR state or not. On occurrence of the sequence (reset sequence) of FIG. 6, sequence detector 430 is designed to reset JTAG lock register 350 via signal 399 (Lock Reset). In response, JTAG lock register resets signal 351 (Lock) to logic zero. As a result, the propagation of the outputs (via path 316) of configuration-and-gating logic 315 to test configuration register 320 is enabled. Also, MUX 345 is configured to forward TDO 312 on path 202. With the communication path 316 between configuration-and-gating logic 315 and test configuration register 320 enabled, IC-1 can be configured for another test (e.g., a memory test, as described below).

Pattern-1 and pattern-2 can be any pre-determined pattern known beforehand to sequence detector 430. It may be observed that the TDI connection (311) is directly connected to sequence detector 430. Since, the TDI path (311) will contain test data during the sequential scan tests, the specific patterns pattern-1 and pattern-2, as well as the overall sequence of FIG. 6 need to be designed to ensure that sequence detector 430 does not generate a false (unintended) reset on path 399. To this end, the specific patterns pattern-1 and pattern-2 may be determined empirically based on observation of the data/signal values of test signals SI-1 and SE, which are respectively also available on the TDI and TMS paths. As an example, during sequential scan test, at least one of the signals SI-1 and SE will be deterministic. Thus, patterns pattern-1 and pattern-2 as well as the overall sequence of FIG. 6 can be designed such that a similar sequence is not encountered (received by sequence detector 430) during the sequential scan tests. Thus, the selection of the sequence of FIG. 6 ensures that sequence detector 430 does not generate a false (unintended) reset on path 399 during the sequential scan tests. In addition, the duration and timing of the sequence of FIG. 6 is designed such that the combination of the Pause DR and pattern-2 portion of the sequence is completed within a pre-determined time of the end of pattern-1.

Following the completion of the sequence of FIG. 6 at t53, tester 110 transmits configuration data on pin 201, with the configuration data designed to set IC 120-1 in memory test mode. The memory test is designed to test memory 335. The configuration data are received by JTAG engine 210 via the TDI input 311. Tester 110 generates clock signals on pin 204, which are available on clock terminal TCK (419), to clock-in the configuration data. In addition, tester 110 may control the value of the signal on pin 203 to control the value of signal TMS (409).

Configuration-and-gating logic 315 decodes the configuration data received from JTAG engine 210, and generates corresponding control/configuration bits to set IC 120-1 in memory test mode. The control/configuration bits or data include those required for enabling memory BIST (Built-in self test) controller 330 to perform the memory test, such as for example, the data width to be used in performing the test, the size of memory 335, etc. In addition, the configuration bits also enable appropriate select signals for controlling the operation of components 325, 340, 410, 420 and 440, as described below.

Based on the configuration data received, configuration-and-gating logic 315 sets bit 321 to logic one. As a result, MUX 340 forwards signal 334 (Pass/Fail) on path 341, DEMUX 325 forwards signal 312 on path 327, DEMUX 410 forwards signal 203 (i.e., signal on pin 203) on path 412 (ME), DEMUX 420 forwards signal 204 on path 422, and DEMUX 440 forwards signal 205 on path 442. Signals 327, 412 (ME) 422 (R/W) and 442, during the configuration phase for memory test are used to configure memory BIST controller 330 for the memory test. In some embodiments, signals 327, 412 (ME), 422 (R/W) and 442 are connected directly to memory BIST controller 330 (as shown in FIGS. 3 and 4) for configuration of memory BIST controller 330. Signal 327 and signal 442 may be used to program the specific nature of memory test (e.g., how much of the memory (i.e., memory depth) is to be tested, and data width of the memory under test) to be performed. Signal 412 (ME) may be used as a ‘memory test’ enable/disable signal. Signal 422 (R/W) may be used to indicate whether write or read is to be performed. In other embodiments, configuration of memory BIST controller 330 for the memory test may be effected via the TDI (311), 409 (TMS), 419 (TCK) and 439 (TRST) connections and via JTAG engine 210, configuration-and-gating logic 315 and test configuration register 320. In some embodiments, pin 205 may not be used or implemented at all (maintaining TMS at logic high for five cycles of TCK can be used to reset JTAG engine 210), and configuration for the memory test is effected via the remaining pins 201, 203 and 204. Further, the specific uses of the pins noted above for specifying configuration for the memory test is provided merely by way of illustration. Other techniques can also be used instead. For example, a single pin (e.g., 201) can be used to transmit configuration data in serial form via path 327 to memory BIST controller 330. Several other possible techniques would be apparent to one skilled in the relevant arts. The configuration phase corresponding to memory test is depicted in FIG. 5 by interval t53-t54 (“Configure Memory”).

At the end of the memory test configuration (i.e., once the control/configuration bits corresponding to the memory test have been set/applied) and prior to the start of the memory test, configuration-and-gating logic 315 sets signal 322 to logic one. In response to signal 322 being logic one, JTAG lock register 350 sets signal 351 (Lock) to logic one. A logic one level of signal 351 (Lock) disables the outputs of configuration-and-gating logic 315 from being forwarded to test configuration register 320. Also, a logic one level of signal 351 selects signal 341 as the output of MUX 345 on pin 202. The sequential scan test configuration effects the following pin configurations:

Pin 201 is connected to path 327.

Pin 202 is connected to path 334 (Pass/Fail).

Pin 203 is connected to path 412.

Pin 204 is connected to path 422.

Assuming that pin 205 and TRST connection of JTAG engine 210 are implemented, pin 205 is connected to path 442.

Memory tests are then performed on memory 335 by memory BIST controller 330. Typically, the memory tests include writing a know data pattern to a memory location in memory 335 and reading back the written data. A comparison of the written and read-back values can indicate potentials faults in memory 335. Paths 331, 332 and 333 respectively represent address, data and control paths connecting Memory BIST controller 330 and memory 335. The result (pass or fail) of the memory test are indicated by memory BIST controller 330 on path 334 (Pass/Fail), which is available on pin 202 and can be read by tester 110. The memory test phase is depicted in FIG. 5 by interval t54-t55 (“Memory Test”).

At the end of the memory test at t55, tester 110 again generates the sequence of FIG. 6 to cause signal 351 to be reset to logic zero.

Thus, it may be appreciated that in interval t50-t51, pins 201, 202, 203 and 204 serve as JTAG connections TDI, TDO, TMS, and TCK for configuring IC 120-1 for sequential scan tests, while in interval t51-t52 they serve as test pins to receive/send test signals corresponding to the sequential scan tests. Similarly, in interval t53-t54, pins 201, 202, 203 and 204 again serve as JTAG connections TDI, TDO, TMS, and TCK for configuring IC 120-1 for memory tests, while in interval t54-t55 they serve as test pins to receive/send test signals corresponding to the memory tests. Pin 205, if implemented, may be used in a similar manner during either of the two tests.

While only two tests (namely, sequential scan tests and memory tests) are described above, other tests may also be performed in the same manner. For example, once the sequence of FIG. 6 is generated following t56, tester 110 can configure IC 120-1 for another test. In such a case, IC 120-1 would contain the circuitry to support such a test, the configuration of the circuitry as well as the test itself can be performed using pins 201-205 in a manner similar to that as described above with respect to sequential scan tests and memory test.

The issuing by tester 110 of the sequence of FIG. 6 at the end of a test (sequential scan test and memory test) along with the detection of the sequence by sequence detector 430 enables the gating-off of the outputs (path 316) of configuration-and-gating logic 315 from reaching test configuration register 320 during a test interval, but enables providing of the outputs (path 316) of configuration-and-gating logic 315 to test configuration register 320 during configuration phases. It may be appreciated that such a facility enables re-use of pins 201-204 and 205 (if implemented) as test pins, in addition to their use as the JTAG pins. It may also be appreciated that the generation of the sequence of FIG. 6 in combination with the ability of sequence detector 430 to detect the sequence enables multiple tests (sequential scan test and memory test) to be performed back-to-back, without requiring to reset JTAG engine 210. The re-use of pins 201-205 reduces the overall pin count per IC for test purposes and enables more ICs to be tested simultaneously.

While the description above is provided specifically with respect to re-using JTAG pins of an IC, it may be appreciated that the techniques can also be used in re-using pins that are used to connect non-functional signals of an IC, i.e., signals that are not associated with signals generated during the functional mode operation of the IC. The specific circuitry required to enable re-use of such pins may vary based on what circuit connections the pins normally provide. However, the above-described technique of using pins (e.g., ‘non-functional-mode’ pins such as JTAG pins TDI, TMS, etc.) to configure corresponding circuit portions for a test during a configuration phase, then re-using the pins as test pins (e.g., SI-1, SE, etc) while maintaining the ‘configured information’ intact (i.e., not affected by changes in signal values on the test pins during testing), followed by re-enabling of configuration of corresponding circuit portions for a next test enables reduction of pin count required for testing an IC.

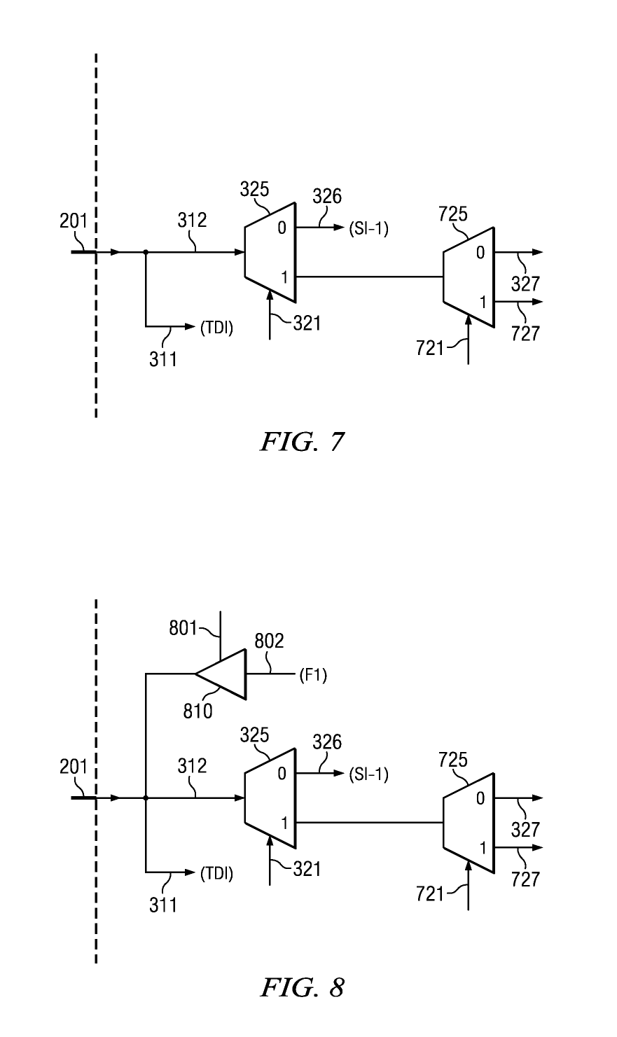

Furthermore, more than two tests can be performed in succession (i.e., back-to-back) using the same set of pins (201-204 or 201-205 in the example of FIGS. 3 and 4) by adding additional circuitry. For example, assuming a third test needs to be performed after the memory test described above, some or all of components 325, 340, 410, 420 and 440 can be implemented as 3:1 MUXes or 1:3 DEMUXes with corresponding generation of a select signal to control the MUXes and DEMUXes. Alternatively a second level of multiplexing or de-multiplexing can be implemented, and example with respect to pin 201 being shown in FIG. 7. In FIG. 7, a second level of de-multiplexing is provided by DEMUX 725. Select signals 321 and 721 are generated by configuration-and-gating logic 315 and the corresponding control values are stored in test configuration register 320. Based on configuration data sent by tester 110, signals 321 and 721 can now be generated to forward the signal on path 312 on one of paths 326, 327 and 727, thereby allowing pin 201 to operate as a test pin (for example a scan-input pin) via path 727 for a third test.

Still further, each of pins 201-205 can be designed to serve additionally as functional pins as well, as shown in the example of FIG. 8. During test (e.g., scan tests and memory tests noted above), signal TRST is maintained at logic one, and during normal functional mode TRST is maintained at logic zero. In addition to the components and connections of FIG. 7, FIG. 8 contains tri-state controllable buffer 810, with input 802 connected to a functional-mode signal F1, the tri-state control (e.g., TRST signal) being provided via terminal 801. In the functional mode of operation, JTAG engine 210 is disabled (TRST is at logic zero), and IC 120-1 operates in normal functional mode. Signal F1 represents a ‘functional-mode’ signal, and is available as an output on pin 201. In test mode, JTAG engine 210 is enabled, buffer 810 is tri-stated, and pin 201 can function either as the TDI input, or the test inputs as described above.

While in the illustrations of FIGS. 3, 4, 7 and 8, although terminals/nodes are shown with direct connections to (i.e., “connected to”) various other terminals, it should be appreciated that additional components (as suited for the specific environment) may also be present in the path, and accordingly the connections may be viewed as being “electrically coupled” to the same connected terminals. In the instant application, power supply and ground terminals are referred to as constant reference potentials.

While various embodiments of the present disclosure have been described above, it should be understood that they have been presented by way of example only, and not limitation. Thus, the breadth and scope of the present disclosure should not be limited by any of the above-described embodiments, but should be defined only in accordance with the following claims and their equivalents.

What is claimed is:

1. An integrated circuit (IC) comprising:
a Joint Test Action Group (JTAG) engine coupled to a first JTAG pin of the IC, the first JTAG pin to receive, from a tester external to the IC, a first configuration signal during a first configuration interval, the first JTAG pin to receive, from the tester, a first test signal during a first test interval, wherein the first test interval is later than the first configuration interval;
a test configuration register coupled to the JTAG engine, the test configuration register to store control data for configuring a first portion of the IC for a first test based on one or more configuration signals including the first configuration signal, the test configuration register being decoupled from the JTAG engine at the end of the first configuration interval and prior to start of the first test interval; and
a sequence detector coupled to the first JTAG pin, the sequence detector to detect a sequence of bits signifying an end of the first test interval, the sequence detector to re-couple the test configuration register to the JTAG engine in response to detecting the sequence of bits.

2. The IC of claim 1, wherein the first JTAG pin is coupled to the test data input (TDI) terminal of the JTAG engine, the IC further comprising:
a second JTAG pin coupled to the test data output (TDO) terminal of the JTAG engine;
a third JTAG pin coupled to the test mode select (TMS) terminal of the JTAG engine; and
a fourth JTAG pin coupled to the test clock (TCK) terminal of the JTAG engine,
wherein at least one of the second JTAG pin, the third JTAG pin and the fourth JTAG pin is coupled to receive a signal to facilitate the provision of the first configuration signal to the JTAG engine during the first configuration interval,
wherein the at least one of the second JTAG pin, the third JTAG pin and the fourth JTAG is coupled to receive a second test signal during the first test interval.

3. The IC of claim 2, wherein the first test is a sequential scan test, wherein the first test signal represents scan-in data, and wherein the second test signal is a scan-enable signal.

4. The IC of claim 3, wherein the first JTAG pin is coupled to receive, from the tester, a second configuration signal during a second configuration interval immediately following the end of the first test interval, the first JTAG pin to receive, from the tester, a third test signal during a second test interval, wherein the second test interval is later than the second configuration interval,
wherein the at least one of the second JTAG pin, the third JTAG pin and the fourth JTAG pin is coupled to receive another signal to facilitate the provision of the second configuration signal to the JTAG engine during the second configuration interval,
wherein the at least one of the second JTAG pin, the third JTAG pin and the fourth JTAG is coupled to receive a fourth test signal during the second test interval.

5. The IC of claim 4, wherein the second test is a memory test designed to uncover faults in a memory comprised in the IC, wherein the third test signal represents a data-width to be used for the memory test, and wherein the fourth test signal is an enable signal used to enable the memory test.

6. The IC of claim 2, further comprising a configuration-and-gating logic, which in combination with the JTAG engine is designed to generate the control data by decoding configuration signals received during the first configuration interval.

7. An integrated circuit (IC) comprising:
a plurality of external pins including a first set of external pins, wherein at least one external pin in the first set of external pins is coupled to receive, during a configuration phase, a configuration signal, wherein the at least one external pin is coupled to receive, during the test, a test signal used in testing the circuit block, wherein the test is designed to uncover faults in the circuit block;
a configuration logic to generate control data by decoding configuration signals received during the configuration phase, wherein the control data is designed to configure the circuit block for the test, wherein the first configuration signal is comprised in the configuration signals;
a test configuration register coupled to the configuration logic during the configuration phase to receive the control data, the test configuration register to store and apply the control data during the test, the test configuration register being decoupled from the configuration logic at the end of the configuration phase and prior to commencement of the test; and
a sequence detector, to detect a reset sequence signifying an end of the test, the sequence detector to re-couple the test configuration register to the configuration logic in response to detecting the reset sequence.

8. The IC of claim 7, wherein the first set of pins are Joint Test Action Group (JTAG) pins, and wherein the configuration logic comprises a JTAG engine, wherein each of the first set of pins is connected to the JTAG engine.

9. The IC of claim 8, wherein the test is a sequential scan test, wherein the circuit block is a scan chain in the IC, wherein the configuration signal is designed to configure the scan chain for the sequential scan test, wherein the test signal represents scan-in data.

10. The IC of claim 8, wherein the test is a memory test, wherein the circuit block is a memory in the IC, wherein the configuration signal is designed to configure the scan chain for the sequential scan test, wherein the test signal represents an enable signal for testing the memory.

11. An integrated circuit comprising:
a plurality of external pins including a first pin, a second pin, a third pin and a fourth pin;
a JTAG engine, wherein TDI, TMS and TCK terminals of the JTAG engine are connected respectively to the first pin, the third pin, and the fourth pin;
a first de-multiplexer (DEMUX), wherein the TDI terminal is connected to an input of the first DEMUX;
a second DEMUX, wherein the TMS terminal is connected to an input of the second DEMUX;
a third DEMUX, wherein the TCK terminal is connected to an input of the third DEMUX;
a first multiplexer (MUX), wherein the TDO terminal of the JTAG engine is connected to a first input of the first MUX, an output of the first MUX being connected to a second pin in the plurality of external pins;
a second MUX, wherein an output of the second MUX is coupled to a second input of the first MUX;
a configuration-and-gating logic coupled to receive a first set of outputs of the JTAG engine;
a test configuration register coupled to the configuration-and-gating logic;
a sequence detector coupled to the TDI terminal, the sequence detector also coupled to receive a second set of outputs of the JTAG engine; and
a JTAG lock register,
wherein each of the first pin, the third pin and the fourth pin is coupled to receive, from an external tester, a corresponding configuration signal during a configuration phase and a corresponding test signal during a test phase designed to uncover faults in the IC, the test phase following the configuration phase,
wherein, the combination of the JTAG engine and the configuration-and-gating logic decode configuration signals received via the first pin, third pin and the fourth pin during the configuration phase to generate control data,
wherein the test configuration register applies the control data to corresponding circuit portions of the IC to be tested, wherein the test configuration register is designed to set an output of the JTAG lock register to a logic one at the end of the configuration phase and prior to the test phase, wherein setting of the output of the JTAG lock register to a logic one decouples the test configuration register from the configuration-and-gating logic thereby preventing test signals received, during the test phase and via the first pin, the third pin and the fourth pin, from changing the control data,
wherein the sequence detector is designed to detect a reset sequence signifying an end of the test phase, the sequence detector to re-couple the test configuration register to the configuration-and-gating logic logic in response to detecting the reset sequence.
